(19) United States
(12) Patent Application Publication
(10) Pub. No.: US 2024/0244923 A1
(43) Pub. Date: Jul. 18, 2024

(54) DISPLAY DEVICE

(71) Applicant: Japan Display Inc., Tokyo (JP)

(72) Inventors: Hayata AOKI, Tokyo (JP); Jun NITTA, Tokyo (JP); Marina MOCHIZUKI, Tokyo (JP)

(73) Assignee: Japan Display Inc., Tokyo (JP)

(21) Appl. No.: 18/411,034

(22) Filed: Jan. 12, 2024

(30) Foreign Application Priority Data
Jan. 17, 2023 (JP) 2023-005111
Feb. 15, 2023 (JP) 2023-021707

(51) Int. Cl. H10K 59/80; H10K 59/122; H10K 59/35; H10K 102/10

(52) U.S. Cl. CPC H10K 59/80518; H10K 59/122; H10K 59/353; H10K 2102/103

(57) ABSTRACT

According to one embodiment, a display device includes a plurality of pixels including at least a first pixel and a second pixel, each of the plurality of pixels comprising an anode including a reflective electrode and a transparent electrode, an organic EL layer provided on the anode, wherein a first anode of the first pixel includes a first reflective electrode and a first transparent electrode, a second anode of the second pixel includes a second reflective electrode and a second transparent electrode, an end portion of the first reflective electrode and an end portion of the first transparent electrode coincide with each other, and the second transparent electrode covers the second reflective electrode.

### CROSS-REFERENCE TO RELATED APPLICATIONS

This application is based upon and claims the benefit of priority from Japanese Patent Applications No. 2023-005111, filed Jan. 17, 2023; and No. 2023-021707, filed Feb. 15, 2023, the entire contents of all of which are incorporated herein by reference.

### FIELD

Embodiments described herein relate generally to a display device.

### BACKGROUND

Organic electroluminescent (organic EL) display devices have been developed, which achieve light emission by utilizing energy at the time of recombination between holes injected from the anode and electrons injected from the cathode.

### BRIEF DESCRIPTION OF THE DRAWINGS

FIG. 1 is an overall perspective view showing a display device of an embodiment.

FIG. 2 is a partial plan view schematically showing a configuration example of the display device.

FIG. 3 is a cross-sectional view of the display device taken along line A1-A2 shown in FIG. 2.

FIG. 4 is a cross-sectional view schematically showing a configuration example of the embodiment.

FIG. 5 is a plan view of pixels shown in FIG. 4.

FIG. 6 is a cross-sectional view schematically showing a configuration example of the embodiment.

FIG. 7 is a cross-sectional view showing a step in a method of manufacturing the display device of the embodiment.

FIG. 8 is a cross-sectional view showing a further step in the method of manufacturing the display device of the embodiment.

FIG. 9 is a cross-sectional view showing a further step in the method of manufacturing the display device of the embodiment.

FIG. 10 is a cross-sectional view showing a further step in the method of manufacturing the display device of the embodiment.

FIG. 11 is a cross-sectional view showing a further step in the method of manufacturing the display device of the embodiment.

FIG. 12 is a cross-sectional view showing a further step in the method of manufacturing the display device of the embodiment.

FIG. 13 is a cross-sectional view showing a further step in the method of manufacturing the display device of the embodiment.

FIG. 14 is a cross-sectional view showing a further step in the method of manufacturing the display device of the embodiment.

FIG. 15 is a cross-sectional view showing a further step in the method of manufacturing the display device of the embodiment.

FIG. 16 is a cross-sectional view showing a further step in the method of manufacturing the display device of the embodiment.

FIG. 17 is a cross-sectional view showing a further step in the method of manufacturing the display device of the embodiment.

FIG. 18 is a cross-sectional view showing a further step in the method of manufacturing the display device of the embodiment.

FIG. 19 is a cross-sectional view showing a further step in the method of manufacturing the display device of the embodiment.

FIG. 20 is a cross-sectional view showing a further step in the method of manufacturing the display device of the embodiment.

FIG. 21 is a cross-sectional view showing a further step in the method of manufacturing the display device of the embodiment.

FIG. 22 is a cross-sectional view showing a further step in the method of manufacturing the display device of the embodiment.

FIG. 23 is a cross-sectional view showing a further step in the method of manufacturing the display device of the embodiment.

FIG. 24 is a cross-sectional view showing a step in a method of manufacturing a display device of a comparative example.

FIG. 25 is a cross-sectional view showing a further step in the method of manufacturing the display device of the comparative example.

FIG. 26 is a cross-sectional view showing a further step in the method of manufacturing the display device of the comparative example.

FIG. 27 is a plan view showing another configuration example of the display device of the embodiment.

### DETAILED DESCRIPTION

In general, according to one embodiment, a display device comprises
a plurality of pixels including at least a first pixel and a second pixel; and
a bank provided between each adjacent pair of the plurality of pixels,
each of the plurality of pixels comprising, on a base,
an anode including a reflective electrode and a transparent electrode,
an organic EL layer provided on the anode,
a protective layer provided on side surfaces of the organic EL layer, and
a cathode provided in apertures of the protective layer and the bank, so as to be in contact with the organic EL layer, wherein
a first anode of the first pixel includes a first reflective electrode and a first transparent electrode,
a second anode of the second pixel includes a second reflective electrode and a second transparent electrode,
an end portion of the first reflective electrode and an end portion of the first transparent electrode coincide with each other, and
the second transparent electrode covers the second reflective electrode.

An object of this embodiment is to provide a display device with improved display quality.

Embodiments will be described hereinafter with reference to the accompanying drawings. Note that the disclosure is merely an example, and proper changes within the spirit of the invention, which are easily conceivable by a skilled person, are included in the scope of the invention as a matter of course. In addition, in some cases, in order to make the description clearer, the widths, thicknesses, shapes, etc. of the respective parts are schematically illustrated in the drawings, compared to the actual modes. However, the schematic illustration is merely an example, and adds no restrictions to the interpretation of the invention. Besides, in the specification and drawings, the same or similar elements as or to those described in connection with preceding drawings or those exhibiting similar functions are denoted by like reference numerals, and a detailed description thereof is omitted unless otherwise necessary.

The embodiments described herein are not general ones, but rather embodiments that illustrate the same or corresponding special technical features of the invention. The following is a detailed description of one embodiment of a display device with reference to the drawings.

In this embodiment, a first direction X, a second direction Y and a third direction Z are orthogonal to each other, but may intersect at an angle other than 90 degrees. The direction toward the tip of the arrow in the third direction Z is defined as up or above, and the direction opposite to the direction toward the tip of the arrow in the third direction Z is defined as down or below. Note that the first direction X, the second direction Y and the third direction Z may as well be referred to as an X direction, a Y direction and a Z direction, respectively.

With such expressions as “the second member above the first member” and “the second member below the first member”, the second member may be in contact with the first member or may be located away from the first member. In the latter case, a third member may be interposed between the first member and the second member. On the other hand, with such expressions as “the second member on the first member” and “the second member beneath the first member”, the second member is in contact with the first member.

Further, it is assumed that there is an observation position to observe the optical control element on a tip side of the arrow in the third direction Z. Here, viewing from this observation position toward the X-Y plane defined by the first direction X and the second direction Y is referred to as plan view. Viewing a cross-section of the display device in the X-Z plane defined by the first direction

X and the third direction Z or in the Y-Z plane defined by the second direction Y and the third direction Z is referred to as cross-sectional view.

### EMBODIMENTS

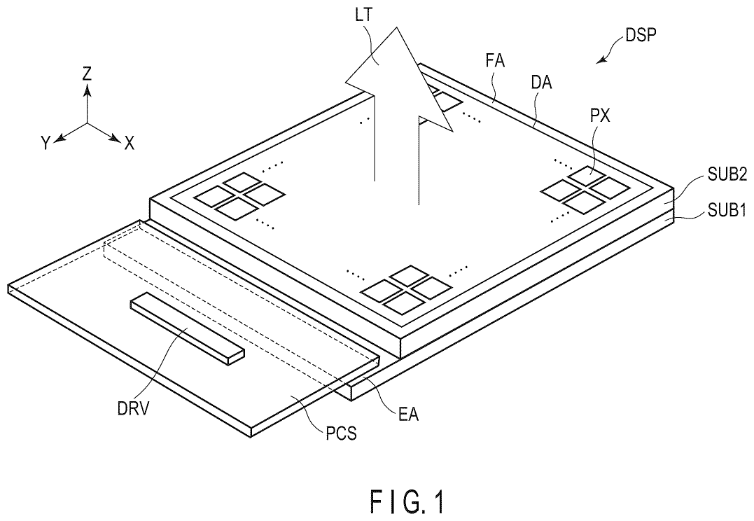

FIG. 1 is an overall perspective view of a display device of an embodiment. A display device DSP comprises a display area DA and a peripheral area FA provided around the display area DA on a substrate SUB1. The display device DSP includes a plurality of pixels PX arranged in the display area DA. In the display device DSP, light LT from the rear surface is transmitted to the front surface and vice versa.

On an upper surface of the display area DA, a substrate SUB2 is provided as a sealing member. The substrate SUB2 is fixed to the substrate SUB1 by a seal material (not shown) provided to surround the display area DA. The display area DA formed on the substrate SUB1 is sealed so as not to be exposed to the atmosphere by the substrate SUB2 as a sealing member and the sealing material.

An area EA in an end portion of the substrate SUB1 is located outside of the substrate SUB2. In the area EA, a wiring circuit board PCS is provided. On the wiring circuit board PCS, a drive element DRV that outputs video signals and drive signals is provided. Signals from the drive element DRV are input to the pixels PX in the display area DA via the wiring circuit board PCS. Based on the video signals and various control signals, the pixels PX emits light.

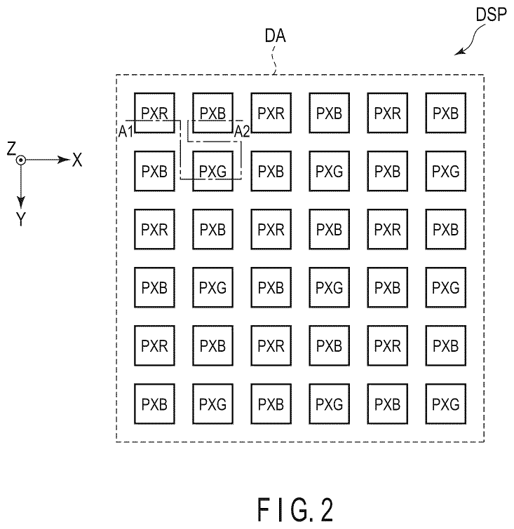

FIG. 2 is a partial plan view schematically showing a configuration example of the display device. The plurality of pixels PX includes pixels PXR which emit red color, pixels PXG which emit green color and pixels PXB which emit blue color. Note that the pixels PXR, the pixels PXG and the pixels PXB may as well be referred to as first pixels, second pixels and third pixels, respectively. Each pixel PXR is disposed next to respective pixels PXB along the first direction X and the second direction Y. Each pixel PXG is disposed next to respective pixels PXB along the first direction X and the second direction Y. Each pixel PXB is disposed next to a respective pixel PXR along the first direction and next to a respective pixel PXG along the second direction Y.

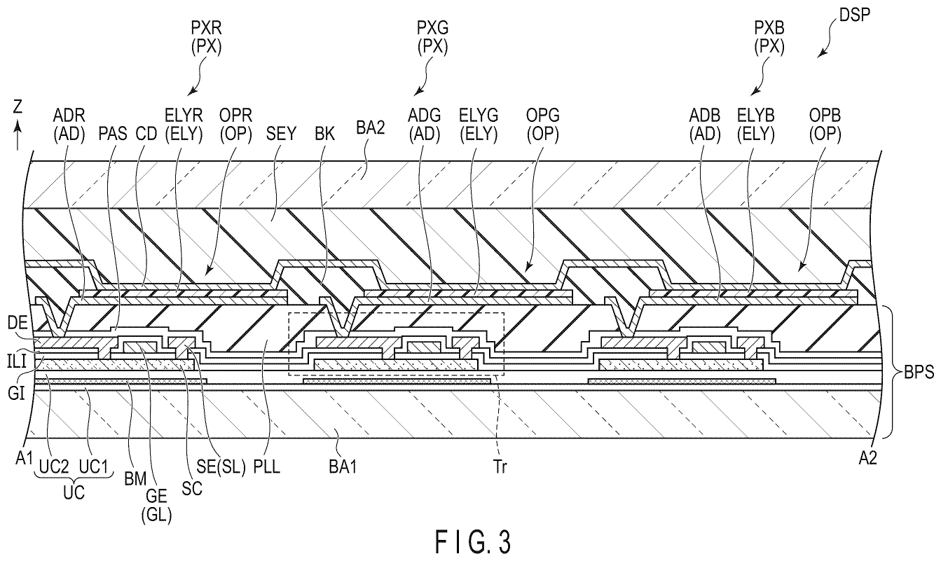

FIG. 3 is a diagram showing a cross-sectional view of the display device taken along line A1-A2 shown in FIG. 2.

A base BA1 is, for example, glass or a base material made of a resin material. For example, acrylic, polyimide, polyethylene terephthalate, polyethylene naphthalate or the like may be used as the resin material, and may be formed from a single layer or a stacked body of multiple layers of any of these.

An insulating layer UC1 is provided on the base BA1. The insulating layer UC1 is formed from, for example, a single layer of a silicon oxide film or silicon nitride film or a stacked body of these layers.

On the insulating layer UC1, a light-shielding layer BM may as well be provided to overlap a transistor Tr. The light-shielding layer BM suppresses changes in transistor characteristics, which may be caused by light penetration or the like from the rear surface of the channel of the transistor Tr. When the light-shielding layer BM is formed of a conductive layer, it is also possible to impart a back-gate effect to the transistor Tr by providing a predetermined potential.

An insulating layer UC2 is provided to cover the insulating layer UC1 and the light-shielding layer BM. For the insulating layer UC2, a material similar to that of the insulating layer UC1 can be used. The insulating layer UC2 may as well be made of a material different from that of the insulating layer UC1. For example, silicon oxide can be used for the insulating layer UC1, whereas silicon nitride for the insulating layer UC2. The insulating layers UC1 and UC2 together may be referred to as insulating layer UC.

The transistor Tr is provided on the insulating layer UC. The transistor Tr includes a semiconductor layer SC, an insulating layer GI, a gate electrode GE (a scanning line), an insulating layer ILI, a source electrode SE (a signal line) and a drain electrode DE.

As the semiconductor layer SC, amorphous silicon, polysilicon or an oxide semiconductor is used.

As the insulating layer GI, for example, silicon oxide or silicon nitride is provided in a single layer or in a stacked body of these layers.

For example, a molybdenum-tungsten alloy (MoW) is used as the gate electrode GE. The gate electrode GE may be formed to be integrated with the scanning line GL.

The insulating layer ILI is provided to cover the semiconductor layer SC and the gate electrode GE. The insulating layer ILI is formed, for example, by a single layer of a silicon oxide layer or silicon nitride layer or a stacked body of these layers.

On the insulating layer ILI, the source electrode SE and the drain electrode DE are provided. The source electrode SE and drain electrode DE are connected to the source region and drain region of the semiconductor layer SC, respectively, via contact holes made in the insulating layer ILI and the insulating layer GI. The source electrode SE may as well be formed to be integrated with the signal line.

An insulating layer PAS is provided to cover the source electrode SE, the drain electrode DE and the insulating layer ILI. Further, an insulating layer PLL is provided to cover the insulating layer PAS.

The insulating layer PAS is formed using an inorganic insulating material. The inorganic insulating material is, for example, a single layer of silicon oxide or silicon nitride or a stacked body of these. The insulating layer PLL is formed using an organic insulating material. The organic insulating material is, for example, an organic material such as photosensitive acrylic, polyimide or the like. With the insulating layer PLL thus provided, steps caused by the transistor Tr can be planarized.

On the insulating layer PLL, an anode AD is provided. The anode AD is connected to the drain electrode DE via contact holes made in the insulating layers PAS and PLL. Note that the anode provided in each pixel PXR is referred to as an anode ADR, the anode provided in each pixel PXB is referred to as an anode ADB, and the anode provided in each pixel PXG is referred to as an anode ADG. When it is not necessary to distinguish the anode ADR, the anode ADG and the anode ADB from each other, they are simply referred to as anodes AD.

Details of the configuration and materials of the anode AD will be described later.

In this embodiment, the configuration from the base BA1 to the insulating layer PLL is referred to as a backplane BPS.

A bank BK (which may as well be referred to as a projecting portion or rib) is provided between each adjacent pair of anodes AD. As the material of the bank BK, an organic material similar to the material of the insulating layer PLL is used. The bank BK is opened to expose a part of the respective anode AD.

An aperture made in each pixel PXR is referred to as an aperture OPR, an aperture made in each pixel PXB is referred to as an aperture OPB, and an aperture made in each pixel PXG is referred to as an aperture OPG. When it is not necessary to distinguish the aperture OPR, the aperture OPB and the aperture OPG from each other, they are simply referred to as apertures OP.

It is preferable that an end portion of each aperture OP should be gently tapered in cross-sectional view. If the end portion of the aperture OP has a steep shape, coverage defects will occur in an organic EL layer ELY that is to be formed later.

The organic EL layer ELY is provided between each adjacent pair of banks BK so as to overlap the respective anode AD. Although the details thereof will be provided later, note that the organic EL layer ELY includes a hole injection layer HIL, a hole transport layer HTL, a light emitting layer EML, an electron transport layer ETY and an electron injection layer EIL. The organic EL layer ELY may further include an electron blocking layer and a hole blocking layer, if necessary.

The organic EL layer provided on each pixel PXR is referred to as an organic EL layer ELYR, the organic EL layer provided on each pixel PXB is referred to as an organic EL layer ELYB, and the organic EL layer provided on each pixel PXG is referred to as an organic EL layer ELYG. When it is not necessary to distinguish the organic EL layer ELYR, the organic EL layer ELYG and the organic EL layer ELYB from each other, they are simply referred to as organic EL layers ELY.

A cathode CD is provided on the organic EL layer ELY. The cathode CD is formed from, for example, a magnesium-silver alloy (MgAg), a single layered film of silver (Ag) or a stacked layered film of silver (Ag) and a transparent conductive material. As the transparent conductive material, for example, indium tin oxide (ITO) or indium zinc oxide (IZO) can be used.

An insulating layer SEY is provided to cover the cathode CD. The insulating layer SEY has a function of preventing moisture from entering the organic EL layer ELY from the outside. As the insulating layer SEY, a material having a high gas barrier property is preferable. As the insulating layer SEY, for example, a layer obtained by sandwiching an organic insulating layer between two inorganic insulating layers containing nitrogen, can be used. Examples of the material for the organic insulating layer are acrylic resin, epoxy resin and polyimide resin. Examples of the material for the inorganic insulating layer containing nitrogen are silicon nitride and aluminum nitride.

A base BA2 is provided on the insulating layer SEY. The base BA2 is formed of a material similar to that of the base BA1. Between the base BA2 and the insulating layer SEY, a translucent inorganic insulating layer or a translucent organic insulating layer may as well be provided. The organic insulating layer may as well have the function of adhering the insulating layer SEY and the base BA2 together.

The light emission generated in the organic EL layer ELY is extracted upward via the cathode CD. In other words, the display device DSP of this embodiment has a top emission structure.

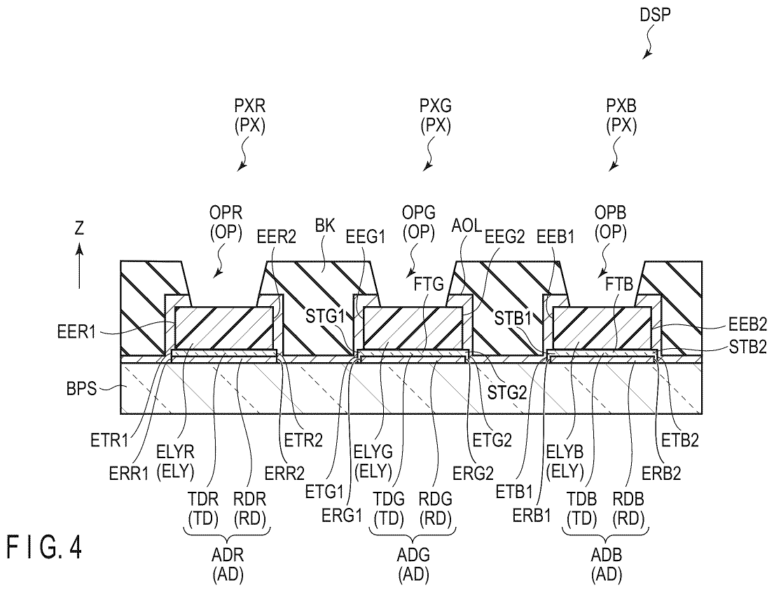

FIG. 4 is a cross-sectional view schematically showing a configuration example of the embodiment. In the display device DSP shown in FIG. 4, only the configuration in the vicinity of the organic EL layer ELY is shown. In FIG. 4, the anodes AD (anode ADR, anode ADG and anode ADB) are provided on the backplane BPS.

The anodes AD each include a reflective electrode RD and a transparent electrode TD. The reflective electrode RD and the transparent electrode TD are stacked in this order along the third direction Z.

The reflective electrode RD is formed using a conductive material with high reflectivity, for example, silver (Ag) and molybdenum-tungsten alloy (MoW). The transparent electrode TD is formed using, for example, indium tin oxide (ITO) and indium zinc oxide (IZO).

The anode ADR includes a reflective electrode RDR and a transparent electrode TDR. The reflective electrode RDR includes an end portion ERR1 and an end portion ERR2. The end portions ERR1 and ERR2 are located to oppose each other. The transparent electrode TDR includes an end portion ETR1 and an end portion ETR2. The end portion ETR1 and the end portion ETR2 are located to oppose each other.

The end portion ERR1 of the reflective electrode RER and the end portion ETR1 of the transparent electrode TDR are coincident with each other along the third direction Z. The end portion ERR2 of the reflective electrode RER and the end portion ETR2 of the transparent electrode TDR are coincident with each other along the third direction Z.

The anode ADG includes a reflective electrode RDG and a transparent electrode TDG. The reflective electrode RDG includes an end portion ERG1 and an end portion ERG2. The end portion ERG1 and the end portion ERG2 are located to oppose each other. The transparent electrode TDG includes a flat portion FTG, a side wall STG1 and a side wall STG2. The side wall STG1 and the side wall STG2 extend from the flat portion FTG in a direction opposite to the third direction Z.

The side wall STG1 of the transparent electrode TDG covers the end portion ERG1 of the reflective electrode RDG. The side wall STG2 of the transparent electrode TDG covers the end portion ERG2 of the reflecting electrode RDG. The end portion ETG1 of the transparent electrode TDG and the end portion ERG1 of the reflective electrode RDG do not coincide with each other. The end portion ETG2 of the transparent electrode TDG and the end portion ERG2 of the reflective electrode RDG do not coincide with each other.

The anode ADB includes a reflective electrode RDB and a transparent electrode TDB. The reflective electrode RDB has an end portion ERB1 and an end portion ERB2. The end portion ERB1 and the end portion ERB2 are located to oppose each other. The transparent electrode TDB has a flat portion FTB, a side wall STB1 and a side wall STB2. The side wall STB1 and the side wall STB2 extend from the flat portion FTB in a direction opposite to the third direction Z.

The side wall STB1 of the transparent electrode TDB covers the end portion ERB1 of the reflective electrode RDB. The side wall STB2 of the transparent electrode TDB covers the end portion ERB2 of the reflective electrode RDB. The end portion ETB1 of the transparent electrode TDB and the end portion ERB1 of the reflective electrode RDG do not coincide with each other. The end portion ETB2 of the transparent electrode TDG and the end portion ERG2 of the reflective electrode RDG do not coincide with each other.

On the anodes AD, the organic EL layers ELY are provided, respectively. On the anode ADR, the organic EL layer ELYR is provided. On the anode ADB, the organic EL layer ELYB is provided. On the anode ADG, the organic EL layer ELYG is provided.

So as to cover side surfaced of each of the anode ADR, the anode ADG, the anode ADB, the organic EL layer ELYR, the organic EL layer ELYG and the organic EL layer ELYB, protective layers AOL are provided, respectively. The protective layers AOL are formed of, for example, aluminum oxide (AlOx).

The banks BK are each provided between each respective adjacent pair of organic EL layers ELY on the protective layer AOL. The apertures OP (the aperture OPR, aperture OPB and apertures OPG) are each provided between each respective adjacent pair of banks BK. Although not shown in FIG. 4, the cathodes CD are provided to cover the banks BK, the organic EL layers ELY and the protective layers AOL.

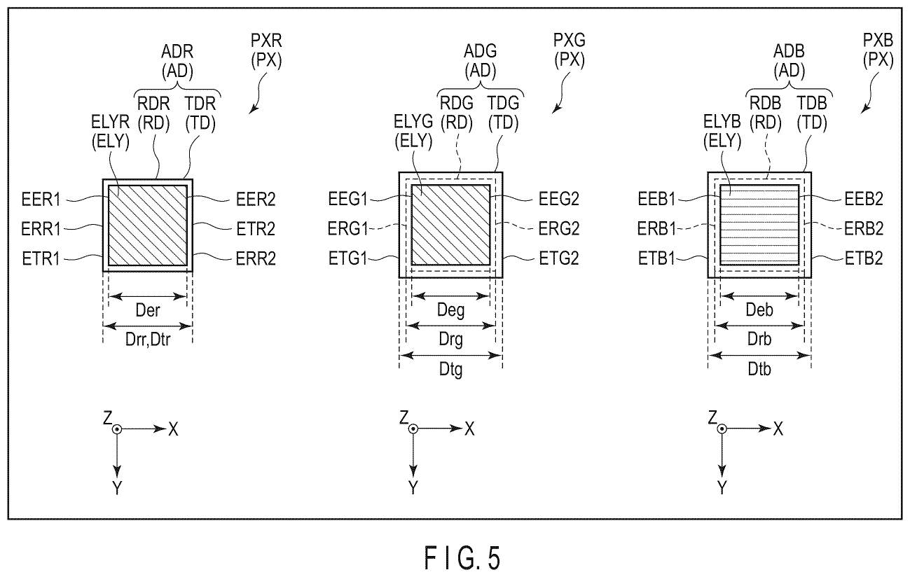

FIG. 5 is a plan view of the pixels shown in FIG. 4. In the pixel PXR, only the organic EL layer ELYR, the reflective electrode RDR and the transparent electrode TDR are illustrated. In the pixel PXG, only the organic EL layer ELYG, the reflective electrode RDG and the transparent electrode TDG are illustrated. In the pixel PXB, only the organic EL layer ELYB, the reflection electrode RDB and the transparent electrode TDB are illustrated.

The length (width) of the organic EL layer ELYR along the first direction X is referred to as Der, the length (width) of the reflective electrode RDR is referred to as Drr, and the length (width) of the transparent electrode TDR is referred to as Dtr. The length (width) of the organic EL layer ELYG along the first direction X is referred to as Deg, the length (width) of the reflective electrode RDG is referred to as Drg, and the length (width) of the transparent electrode TDG is referred to as Dtg. The length (width) of the organic EL layer ELYB along the first direction X is referred to as Deb, the length (width) of the reflective electrode RDB is referred to as Drb, and the length (width) of the transparent electrode TDB is referred to as Dtb.

For example, the length Der, the length Deg and the length Deb are equal to each other (Der=Deg =Deb). The length Drr and the length Dtr are equal to each other (Drr=Dtr). The length Drr and the length Dtr are great than the length Der (Drr=Dtr>Der).

The length Dtg is greater than the length Drg, and the length Drg is greater than the length Deg (Dtg>Drg>Deg). The length Dtb is greater than the length Drb, and the length Drb is greater than the length Deb (Dtb>Drb>Deb).

The length DRr, the length Drg and the length Drb may be equal to or different from each other. The length Dtg and the length Dtb may be equal to or different from each other.

The length Dtg and the length Dtb are greater than the length Dtr (Drg, Drb>Drr). This is because, as mentioned above, the transparent electrode TDG and the transparent electrode TDB cover the reflective electrode RDG and the reflective electrode RDB, whereas the end portions of the reflective electrode RDR and the transparent electrode TDR are coincident with each other.

FIG. 6 is a cross-sectional view schematically showing a configuration example of the embodiment. FIG. 6 is a partially enlarged view of the illustration of FIG. 4. As shown in FIG. 6, between the anode AD and the cathode CD, the organic EL layer ELY is provided along the third direction Z. The organic EL layer ELY includes a hole injection layer

HIL, a hole transport layer HTL, a light emitting layer EML, an electron transport layer ETL and an electron injection layer EIL, which are stacked one on another along the third direction Z.

Note that in the display device DSP of this embodiment, the anode AD, the organic EL layer ELY and the cathode CD are stacked along the third direction Z in this order. In the organic EL layer ELY, the hole injection layer HIL, the hole transport layer HTL, the light emitting layer EML, the electron transport layer ETL and the electron injection layer EIL are stacked along the third direction Z. Note that this embodiment is not limited to this configuration described above. In this embodiment of the display device DSP, they may as well be stacked in the order of the cathode CD, the organic EL layer ELY and the anode AD. Further, in the organic EL layer ELY, they may as well be stacked in the order of the electron injection layer EIL, the electron transport layer ETL, the light emitting layer EML, the hole transport layer HTL and the hole injection layer HIL.

Although not shown in FIG. 6, a light extraction layer and a sealing layer may as well be provided on the cathode CD. For example, the insulating layer SEY shown in FIG. 3 functions as a sealing layer.

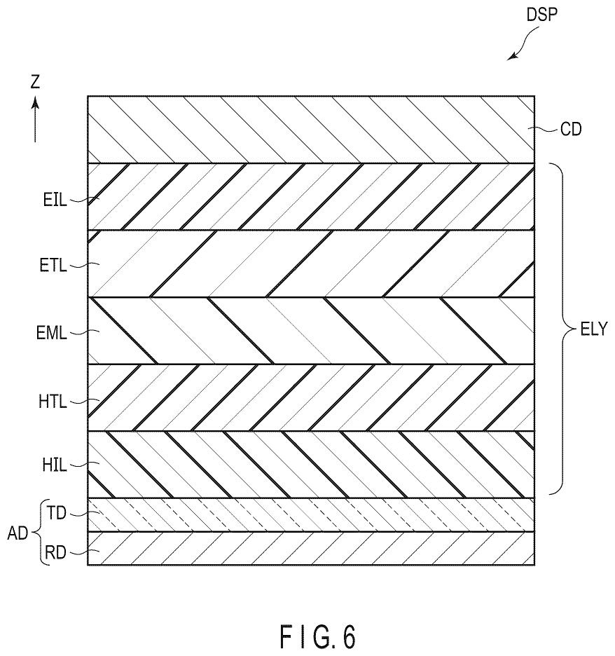

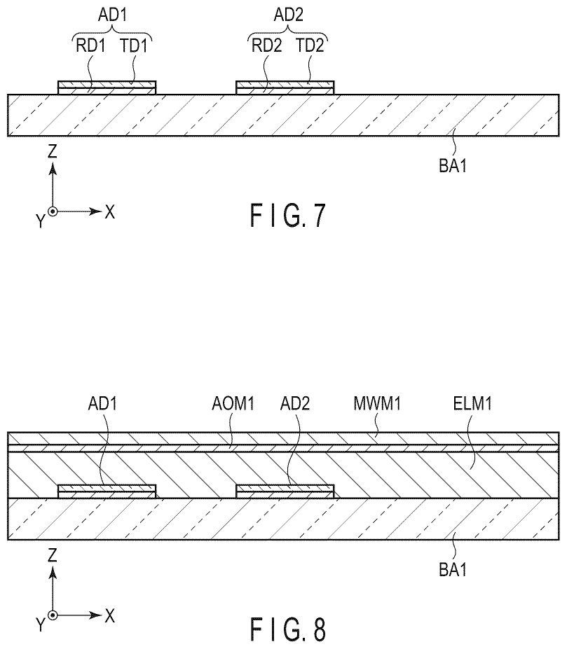

FIGS. 7 to 23 each are a cross-sectional view showing a processing step of a method of manufacturing the display device of the embodiment. In FIGS. 7 to 23, the first pixel, which is one of the pixel PXR, pixel PXG and pixel PXB, is designated as a pixel PX1, and the second pixel, which is another one, is designated as a pixel PX2. In FIGS. 7 to 23, the pixels are formed in the order of the first pixel (pixel PX1) and the second pixel (pixel PX2). The third pixel (pixel PX3), which is the other one of the pixel PXR, pixel PXG and pixel PXB, is formed in a manner similar to that of the first pixel and the second pixel, though not shown in the drawing.

First, an anode AD1 and an anode AD2 are formed on a base BA1 (see FIG. 7). The anode AD1 is the anode of the pixel PX1, and the anode AD2 is the anode of the pixel PX2. The anode AD1 includes a reflective electrode RD1 and a transparent electrode TD1. The anode AD2 includes a reflective electrode RD2 and a transparent electrode TD2.

An organic EL layer ELM1, a sacrificial layer AOM1 and a sacrificial layer MWM1 are formed to cover the base BA1, the anode AD1 and the anode AD2 (see FIG. 8). The organic EL layer ELM1 is the organic EL layer corresponding to the pixel PX1. It should be assumed here that the organic EL layer ELM1 includes the hole injection layer HIL, the hole transport layer HTL, the light emitting layer EML and the electron transport layer ETL, among the hole injection layer HIL, the hole transport layer HTL, the light emitting layer EML, the electron transport layer ETL and the electron injection layer EIL shown in FIG. 6.

The sacrificial layer AOM1 is formed, for example, of aluminum oxide (AlOx). The aluminum oxide layer can be formed by the atomic layer deposition (ALD) method.

The sacrificial layer MWM1 is formed, for example, of molybdenum-tungsten (MoW). The nolybdenum-tungsten layer can be formed by the sputtering method.

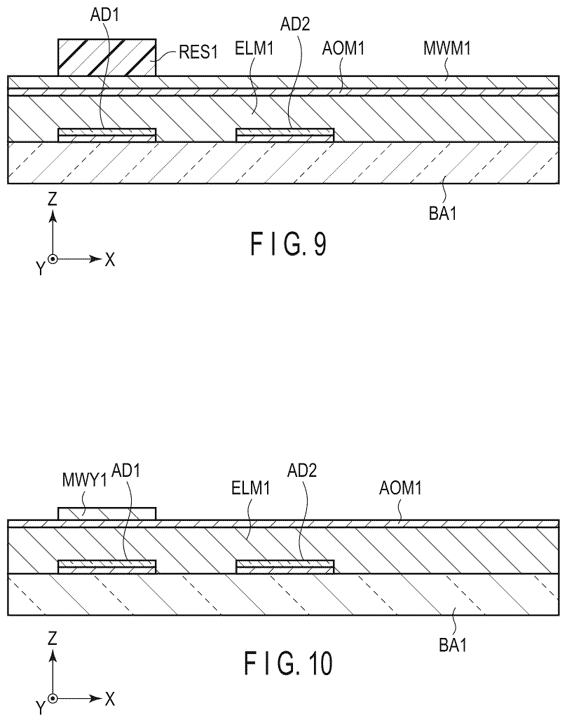

A resist mask RES1 is formed on the sacrificial layer MWM1 so as to oppose the anode AD1 (see FIG. 9). No resist mask is formed on the anode AD2. The length of the resist mask RES1 along the first direction X is set shorter than the length of the anode AD1. In consideration of the bonding of the anode AD and the resist mask RES1, the length of the organic EL layer ELY1 along the first direction X, which is to be formed later, should preferably be made shorter than the length of the anode AD1 (the reflective electrode RD1 and the transparent electrode TD1).

Using the resist mask RES1, the sacrificial layer MWM1 is partially removed by etching. As a result, the sacrificial layer MWY1 is formed into an island shape, so as to oppose the anode AD1 and sandwich the sacrificial layer AOM1 (see FIG. 10).

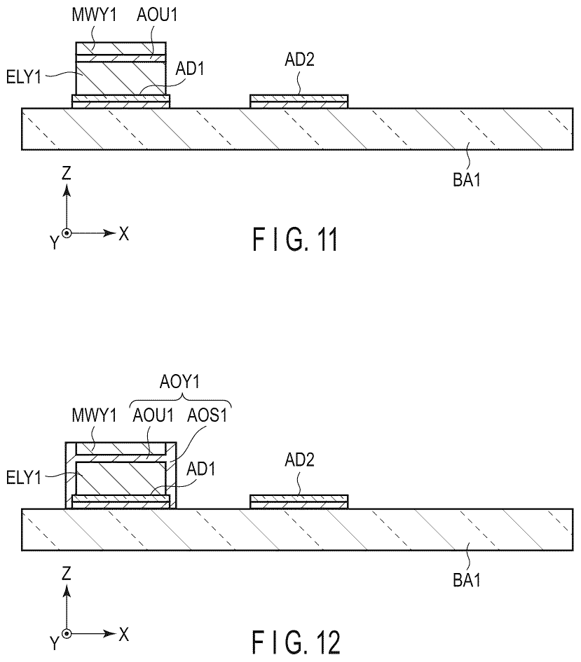

Using the island-shaped sacrificial layer MWY1 as a mask, the sacrificial layer AOM1 and the organic EL layer ELM1 are partially removed by etching. As a result, the organic EL layer ELY1 and an upper layer AOU1 of the sacrificial layer are formed into an island shape between the anode AD1 and the sacrificial layer MWY1 (see FIG. 11). The sacrificial layer AOM1 and the organic EL layer ELM1 on the anode AD2 are removed.

A side wall AOS1 is formed in contact with the side surfaces of the anode AD1, the organic EL layer ELY1, the upper layer AOU1 and the sacrificial layer MWY1. The side wall AOS1 is formed of the same material as that of the sacrificial layer AOM1. The upper layer AOU1 and the side wall AOS1 are altogether referred to as a sacrificial layer AOY1 (see FIG. 12).

In order to form the side wall AOS1, first, a material film which gives rise to the side wall AOS1 is formed so as to cover the stacked body of the organic EL layer ELY1, the upper layer AOU1 and the sacrificial layer MWY1. Then, the material film is subjected to anisotropic etching to remove the entire regions except for only the region in contact with the side surfaced of the stacked body.

During the anisotropic etching, the transparent electrode TD2 of the anode AD2 may be etched away. Both the material film giving rise to the side walls AOS1 and the transparent electrode TD2 are formed of materials containing metal oxides. When etching such metal oxides, it may be necessary to use an etching gas whose selectivity cannot be taken. If an etching gas whose selectivity cannot be taken is used, the transparent electrode TD2 may be etched away as described above, which causes dissipation of the transparent electrode TD2 or excessive reduction of the film thickness of the transparent electrode TD2.

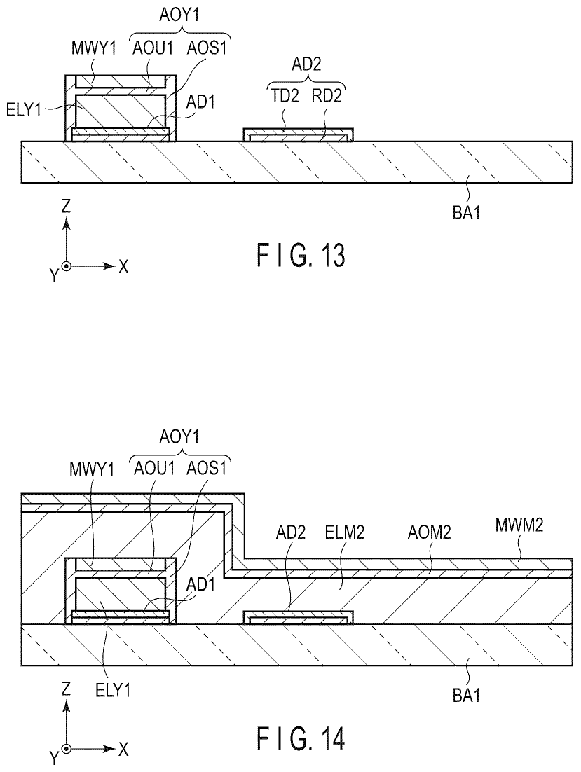

Under these circumstances, the transparent electrode TD2 is formed once again to cover the reflection electrode RD2 (see FIG. 13). The transparent electrode TD2 thus formed again covers the side surfaces of the reflection electrode RD2. The reflection electrode RD2 and the transparent electrode TD2 constitute the anode AD2. Here, note that the length of the transparent electrode TD2 along the first direction X is greater than the length of the reflective electrode RD1 along the first direction X (see FIGS. 4 and 5).

The material of the transparent electrode TD2 formed in the processing step of FIG. 13 maybe different from the material of the transparent electrode TD2 shown in FIG. 7. For example, the transparent electrode TD2 shown in FIG. 7 maybe formed of indium tin oxide (ITO), whereas the transparent electrode TD2 shown in FIG. 13 maybe formed of indium zinc oxide (IZO). Note that indium tin oxide requires a firing process, but the organic EL layer ELY1 may be affected by the temperature of the firing. Therefore, indium zinc oxide (IZO), which does not require firing, is suitable for the transparent electrode TD2 shown in FIG. 13. In other words, the anode AD2 may as well be a transparent electrode TD2 formed from a reflective electrode RD and indium zinc oxide (IZO). In the case where the indium tin oxide (ITO) of the transparent electrode TD2 shown in FIG. 7 remains though its film thickness becomes thinner by anisotropic etching, the transparent electrode TD2 shown in FIG. 13 mayas well be a stacked layer of the indium tin oxide (ITO) thus having the thinner film thickness and newly formed indium zinc oxide (IZO).

An organic EL layer ELM2, a sacrificial layer AOM2 and a sacrificial layer MWM2 are formed to cover the base BA1, the sacrificial layer AOY1, the sacrificial layer MWY1 and the anode AD2 (see FIG. 14). The organic EL layer ELM2 is an organic EL layer corresponding to the pixel PX2. It is assumed here that the organic EL layer ELM2, as in the case of the organic EL layer ELM1, includes a hole injection layer HIL, a hole transport layer HTL, a light emitting layer EML and an electron transport layer ETL, among the hole injection layer HIL, the hole transport layer HTL, the light emitting layer EML, the electron transport layer ETL and the electron injection layer EIL shown in FIG. 6.

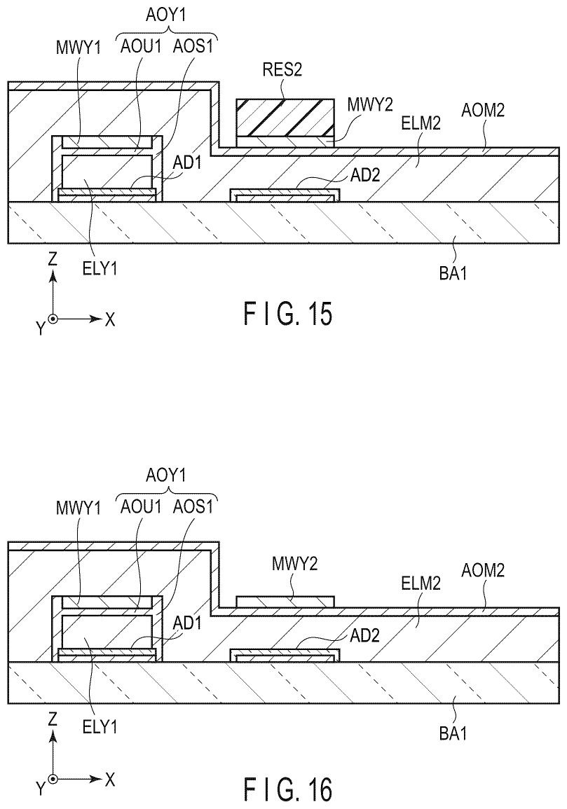

A resist mask RES2 is formed on the sacrificial layer MWM2 so as to oppose the anode AD2. Using the resist mask RES2, the sacrificial layer MWM2 is partially removed by etching. In this manner, a sacrificial layer MWY2 is formed into an island shape so as to oppose the anode AD2 while sandwiching the sacrificial layer AOM2 (see FIG. 15).

The length of the resist mask RES2 along the first direction X is set shorter than the length of the anode AD2, in particular, the reflective electrode RD2. Thus, the length of the organic EL layer ELY2 along the first direction X, which is formed later, can be made shorter than the length of the anode AD2 (the reflective electrode RD2 and the transparent electrode TD2).

Next, the resist mask RES2 is removed (see FIG. 16).

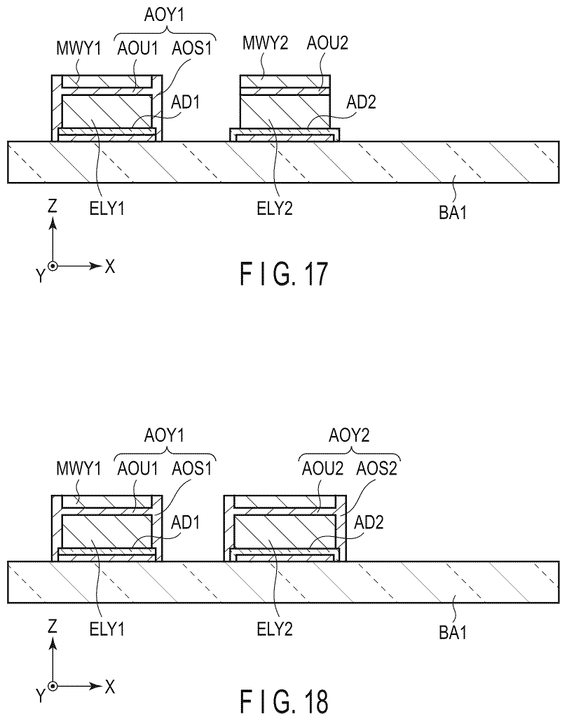

Using the island-shaped sacrificial layer MWY2 as a mask, the sacrificial layer AOM2 and the organic EL layer ELM2 are partially removed by etching. Thus, the organic EL layer ELY2 and an upper layer AOU2 of the sacrificial layer are formed into an island shape between the cathode CD2 and the sacrificial layer MWY2 (see FIG. 17).

Side walls AOS2 are formed in contact with respective side surfaces of each of the anode AD2, the organic EL layer ELY2, the upper layer AOU2 and the sacrificial layer MWY2. The side walls AOS2 are formed of the same material as that of the sacrificial layer AOM2. The upper layer AOU2 and the side walls AOS2 altogether form a sacrificial layer AOY2 (see FIG. 18).

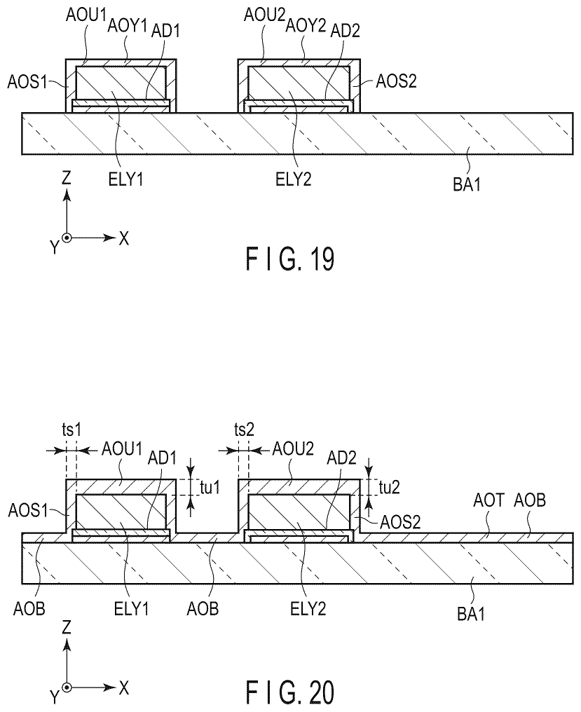

Then, the sacrificial layer MWY1 and the sacrificial layer MWY2 are removed (see FIG. 19). At this time, the upper layer AOU1 of the sacrificial layer AOY1 and the upper layer AOU2 of the sacrificial layer AOY2 are planarized.

So as to cover the upper layer AOU1 and the side walls AOS1 of the sacrificial layer AOY1 and the upper layer AOU2 and the side walls AOS2 of the sacrificial layer AOY2, a sacrificial layer is formed of the same material as that of these sacrificial layers, namely, the sacrificial layer AOM1 and the sacrificial layer AOM2. In this manner, the upper layer AOU1, the side walls AOS1, the upper layer AOU2, the side walls AOS2 and the newly formed sacrificial layer are integrated as one body to form a sacrificial layer AOT (see FIG. 20).

With the above-described configuration, a thickness tu1 of the upper layer AOU1 and a thickness tu2 of the upper layer AOU2 are greater than a thickness ts1 of the side walls AOS1 and a thickness ts2 of the side walls AOS2, respectively. The region of the sacrificial layer AOT, which is in contact with the base BA1 is referred to as a region AOB. A thickness tb of the region AOB should only be the same as the thickness ts1 and the thickness ts2.

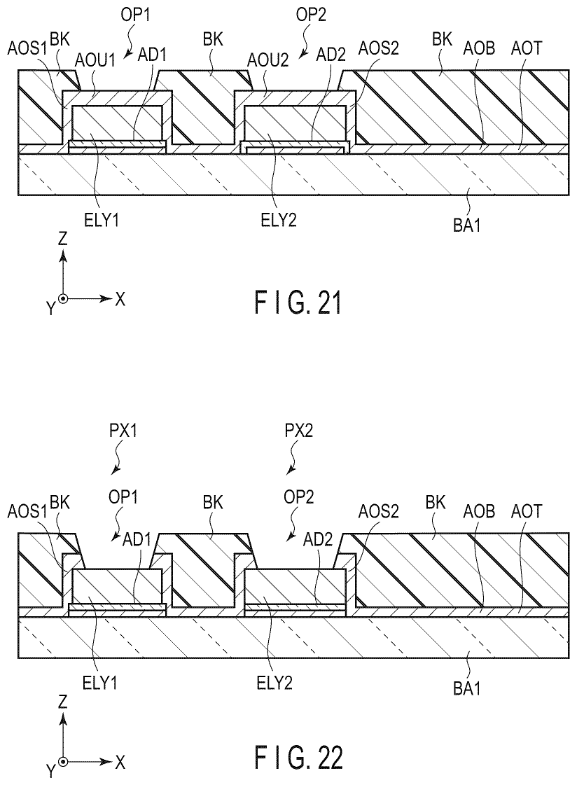

Banks BK are each formed between the organic EL layer ELY1 and the organic EL layer ELY2 so as to be in contact with the sacrificial layer AOT. The banks BK are not formed above the organic EL layer ELY1 or the organic EL layer ELY2. That is, an aperture OP1 and an aperture OP2 are formed above the organic EL layer ELY1 and the organic EL layer ELY2, respectively (see FIG. 21).

Then, the sacrificial layer AOT in the aperture OP1 and the aperture OP2 is removed. With this configuration, the organic EL layer ELY1 and the organic EL layer ELY2 are exposed in the aperture OP1 and the aperture OP2 in the banks BK and the sacrificial layer AOT, respectively (see FIG. 22).

A cathode CD, an insulating layer INS and an insulating layer PCL are formed so as to cover the exposed organic EL layer ELY1 and organic EL layer ELY2 and the banks. On the insulating layer PCL, the base BA2 is provided. Although not illustrated in the figure, an electron injection layer EIL may as well be formed to be in contact with the cathode CD.

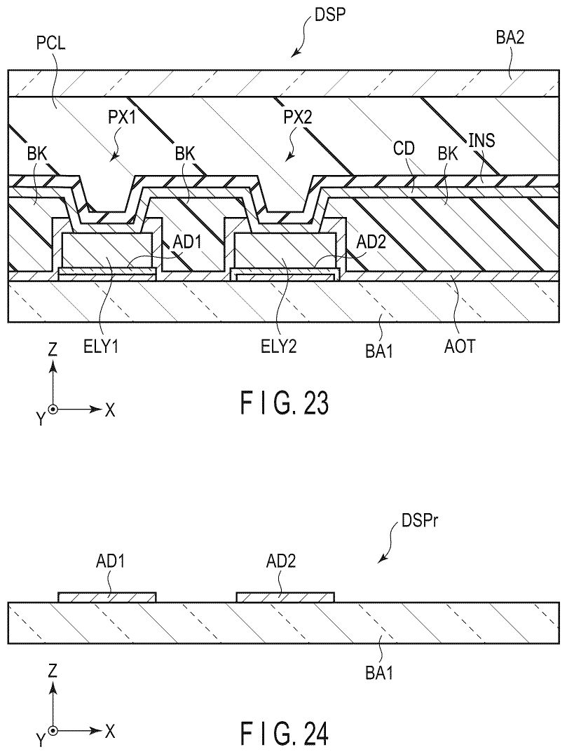

In the aperture OP1 and the aperture OP2, the cathode CD is provided on the organic EL layer ELY1 and the organic EL layer ELY2, respectively. As described above, thus, the display device DSP of the embodiment is formed (see FIG. 23).

The insulating layer INS is formed, for example, of silicon nitride (SiN). The insulating layer INS prevents moisture from entering the organic EL layer from the outside. The insulating layer PCL is formed, for example, of a resin insulating material. The insulating layer PCL has the function of planarizing the surface. For the base BA2, a material similar to that of the base BA1 should be used.

In order to form the anode and the organic EL layer of the third pixel, which is a pixel PX3, an organic EL layer and two sacrificial layers should be formed to cover the anode of the pixel PX3, as in the case shown in FIG. 14, after the completion of the processing step shown in FIG. 18. As in the case shown in FIG. 18, after forming the side walls of the sacrificial layers of the pixel PX3, the process should proceed to that shown in FIG. 19.

The sacrificial layer AOT (sacrificial layer AOY1, sacrificial layer AOY2, side wall AOS1, side wall AOS2 and area AOB) corresponds to the protective layer AOL shown in FIG. 4. The protective layer AOL (sacrificial layer AOT) formed of aluminum oxide can protect the organic EL layer by covering the side surfaces of the organic EL layer.

FIGS. 24 to 26 are cross-sectional views each showing a processing step in a method of manufacturing a display device in a comparative example. In order to manufacture a display device DSPr in the comparative example, first, an anode AD1 and an anode AD2 are formed on the base BA1 (see FIG. 24). The anode AD1 and the anode AD2 in the comparative example are assumed to be transparent electrodes formed of metal oxides. Such metal oxides include indium tin oxide and indium zinc oxide described above. Note that the processing step shown in FIG. 24 corresponds to the step shown in FIG. 7.

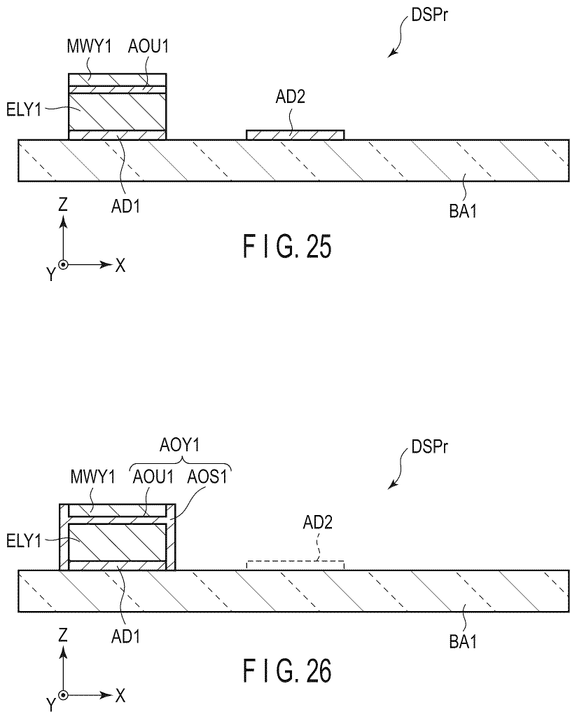

Through the processing steps shown in FIGS. 8 to 10, an organic EL layer ELY1, an upper layer AOU1 of a sacrificial layer and a sacrificial layer MWY1 are formed on the anode AD1. On the anode AD2, the sacrificial layer is removed (see FIG. 25). The processing step shown in FIG. 25 corresponds to the step shown in FIG. 11.

Next, as in the case shown FIG. 12, side walls AOS1 are formed so as to be in contact with side surfaces of each of the anode AD1, the organic EL layer ELY1, the upper layer AOU1 and the sacrificial layer MWY1 (see FIG. 25). In a manner similar to that described above, a material film which give rise to the side walls AOS1 is formed to cover the stacked body of the organic EL layer ELY1, the upper layer AOU1 and the sacrificial layer MWY1. Then, the material film is subjected to anisotropic etching to leave only the area in contact with the side surfaces of the stacked body and remove the other areas, and thus the side walls AOS1 are formed.

The material of the side walls AOS1 is the same as that of the sacrificial layer AOM1, which is, for example, aluminum oxide (AlOx). On the other hand, the anode AD1 and the anode AD2 are formed of metal oxide, for example, as described above.

That is, the side walls AOS1, as well as the anode AD1 and the anode AD2, are formed of a material containing a metal oxide. When etching such metal oxides, it is, in some cases, necessary to use an etching gas whose selectivity cannot be taken.

In this case, during the etching to form the side walls AOS1, the anode AD2 may as well be removed together (see FIG. 26). If the anode is removed, the pixel will not emit light properly. In such a display device, the display quality is deteriorated.

In the display device DSP of the embodiment, the anode is formed of a reflective electrode and a transparent electrode. In the first pixel PX1, which is formed first, the respective end portions of the reflective electrode RD1 and the transparent electrode TD1 coincide with each other. In the second pixel PX2, which is formed next, the transparent electrode TD2 covers the reflection electrode RD2. Although not shown in FIGS. 7 to 23, from the third pixel on, they are formed in a manner similar to that of the second pixel PX2. The display device DSP of this embodiment can be manufactured without losing any anodes in the manufacturing process shown in FIGS. 7 to 23. Therefore, the light emission is always properly carried out by the pixels, and thus it is possible to prevent the deterioration in display quality of the display device DSP.

### Configuration Example 1

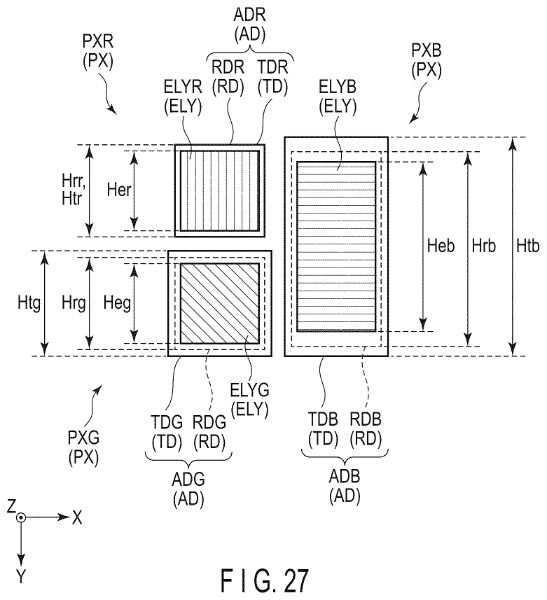

FIG. 27 is a plan view showing another configuration example of the display device in the embodiment. The configuration example shown in FIG. 27 is different from that shown in FIG. 2 in that the size of the pixel which emits blue color is greater than the size of the pixels which emit red and green, respectively.

In FIG. 27, a pixel PXR is arranged adjacent to a pixel PXB along the first direction X. The pixel PXR is located adjacent to a pixel PXG along the second direction Y.

A pixel PXG is arranged adjacent to the pixel PXB along the first direction X. The pixel PXG is arranged adjacent to the pixel PXR along the second direction Y.

The pixel PXB is arranged adjacent to the pixel PXR and the pixel PXG along the first direction X. Further, the pixel PXB is arranged adjacent to another pixel PXB along the second direction Y.

The pixel PXR includes a reflective electrode RDR, a transparent electrode TDR and an organic EL layer ELYR. The reflective electrode RDR and the transparent electrode TDR constitute an anode ADR.

The pixel PXG includes a reflective electrode RDG, a transparent electrode TDG and an organic EL layer ELYG. The reflective electrode RDG and the transparent electrode TDG constitute an anode ADG.

The pixel PXB includes a reflective electrode RDB, a transparent electrode TDB and an organic EL layer ELYB. The reflective electrode RDB and the transparent electrode TDB constitute an anode ADB.

The sizes of the constituent elements of the pixel PXR and the pixel PXB shown in FIG. 27 are substantially the same as those of the case shown in FIG. 5. The lengths of the components of the pixel PXB along the first direction X are substantially the same as the respective ones of those shown in FIG. 5. On the other hand, in the organic EL layer ELYB and the anode ADB (reflective electrode TDB and transparent electrode TDB) of the pixel PXB, the respective lengths along the second direction Y are greater than those of the corresponding components of the pixel PXR and the pixel PXG.

The lengths along the second direction Y of the organic EL layer ELYR, the reflective electrode RDR and the transparent electrode TDR of the pixel PXR are referred to as a length Her, a length Hrr and a length Htr, respectively. The lengths along the second direction Y of the organic EL layer ELYG, the reflective electrode RDG and the transparent electrode TDG of the pixel PXG are referred to as a length Heg, a length Hrg and a length Htg, respectively. The lengths along the second direction Y of the organic EL layer ELYB, the reflective electrode RDB and the transparent electrode TDB of the pixel PXB are referred to as a length Heb, a length Hrb and a length Htb, respectively.

The length Her of the organic EL layer ELYR and the length Heg of the organic EL layer ELYG should be the same (Her=Heg). The length Heb of the organic EL layer ELYB is greater than the length Her and the length Heg (Heb>Her, Heg).

The length Hrr of the reflective electrode RDR and the length Htr of the transparent electrode TDR of the pixel PXR are the same as each other (Hrr=Htr). The length Hrr of the reflective electrode RDR of the pixel PXR, the length Hrg of the reflective electrode RDG of the pixel PXG and the length Hrb of the reflective electrode RDB of the pixel PXB are greater in this order (Hrr<Hrrg<Hrb).

The length Htr of the transparent electrode TDR of the pixel PXR, the length Htg of the transparent electrode TDG of the pixel PXG and the length Htb of the transparent electrode TDB of the pixel PXB are greater in this order (Htr<Htg<Htb).

This configuration example as well exhibit advantageous effects similar to those of the embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A display device comprising:
a plurality of pixels including at least a first pixel and a second pixel; and
a bank provided between each adjacent pair of the plurality of pixels,
each of the plurality of pixels comprising, on a base,
an anode including a reflective electrode and a transparent electrode,
an organic EL layer provided on the anode,
a protective layer provided on side surfaces of the organic EL layer, and
a cathode provided in apertures of the protective layer and the bank, so as to be in contact with the organic EL layer, wherein
a first anode of the first pixel includes a first reflective electrode and a first transparent electrode,
a second anode of the second pixel includes a second reflective electrode and a second transparent electrode,
an end portion of the first reflective electrode and an end portion of the first transparent electrode coincide with each other, and
the second transparent electrode covers the second reflective electrode.

2. The display device according to claim 1, wherein
the first transparent electrode and the second transparent electrode include indium tin oxide or indium zinc oxide.

3. The display device according to claim 1, wherein
the protective layer is formed of aluminum oxide.

4. The display device according to claim 1, wherein
a width of the second anode is greater than a width of the first anode.

5. The display device according to claim 1, wherein
the plurality of pixels further include a third pixel,
a third anode of the third pixel includes a third reflective electrode and a third transparent electrode, and
the third transparent electrode covers the third reflective electrode.

6. The display device according to claim 5, wherein
a width of the third anode is greater than the width of the first anode.
